(19) United States
(12) Patent Application Publication
(10) Pub. No.: US 2012/0028386 A1
(43) Pub. Date: Feb. 2, 2012

(54) Method of manufacturing organic light emitting display

(76) Inventor: In-Young Jung, Yongin-City (KR)

(21) Appl. No.: 13/067,192

(22) Filed: May 16, 2011

(30) Foreign Application Priority Data
May 17, 2010 (KR) 10-2010-0046025

(51) Int. Cl. H01L 51/56

(52) U.S. Cl. 438/23; 257/E51.018

(57) ABSTRACT

A method of manufacturing an organic light-emitting display device, the method including forming a thin film transistor (TFT); forming a planarization layer on the TFT; forming an opening in the planarization layer; and forming an organic light emitting diode that is electrically connected to the TFT through the opening, wherein forming the opening in the planarization layer includes forming a photosensitive layer on the planarization layer, and irradiating light on the photosensitive layer such that the light has a focus point offset from a surface of the planarization layer to control a gradient of the opening.

### BACKGROUND

1. Field

Embodiments relate to a method of manufacturing an organic light-emitting display.

2. Description of the Related Art

An organic light-emitting device is a self-emission type display device that emits light by electrically exciting a phosphor organic compound. The organic light-emitting device may be driven at a low voltage, may be thin, and may have advantages, e.g., a wide viewing angle, good contrast, and fast response speeds. Thus, organic light-emitting devices are highlighted as display devices of the next generation.

The organic light-emitting device may include a light-emitting layer including an organic material between an anode and a cathode. In the organic light-emitting device, as positive and negative voltages are applied to the anode and the cathode, injected holes are moved to the light-emitting layer through a hole transport layer, electrons are moved from the cathode to the light-emitting layer through an electron transport layer, and the holes and the electrons are recombined with each other to generate excitons.

As the excitons change from an excited state to a ground state, phosphor molecules of the light-emitting layer emit light to form an image. A full-color type organic light-emitting device includes a pixel for realizing red (R), green (G) and blue (B) colors, thereby realizing full color.

### SUMMARY

Embodiments are directed to a method of manufacturing an organic light-emitting display, which represents advances over the related art.

It is a feature of an embodiment to provide a method of manufacturing an organic light-emitting display in which flatness of the planarization layer is increased while simultaneously facilitating a reduction in a gradient of a resultant opening formed in the planarization layer, thereby reducing an error rate.

At least one of the above and other features and advantages may be realized by providing a method of manufacturing an organic light-emitting display device, the method including forming a thin film transistor (TFT); forming a planarization layer on the TFT; forming an opening in the planarization layer; and forming an organic light emitting diode that is electrically connected to the TFT through the opening, wherein forming the opening in the planarization layer includes forming a photosensitive layer on the planarization layer, and irradiating light on the photosensitive layer such that the light has a focus point offset from a surface of the planarization layer to control a gradient of the opening.

The focus point of light irradiated onto the photosensitive layer may be offset away from the TFT to reduce the gradient of the opening.

The planarization layer may include at least one of acryl, polyimide, and benzocyclobutene (BCB).

Forming the opening in the planarization layer may include aligning a mask on the photosensitive film, removing portion of the photosensitive layer irradiated with the light, and etching the planarization layer through removed portions of the photosensitive layer.

Irradiating light on the photosensitive layer may include offsetting the focus of light that is irradiated thereon.

Offsetting the focus of light may include offsetting the focus point by about 15 μm to about 30 μm.

Forming the organic light emitting diode that is electrically connected to the TFT through the opening may include forming a plurality of first electrodes that are electrically connected to the TFT through the opening; forming a plurality of pixel defining layers between the first electrodes; forming a plurality of organic layers on the first electrodes; and forming a second electrode on the pixel defining layers and the organic layers.

Irradiating the light on the photosensitive layer such that the light has a focus point offset from a surface of the planarization layer may include offsetting the focus point by about 15 μm to about 30 μm from the surface of planarization layer.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 illustrates a cross-sectional view of an organic light-emitting diode (OLED) display device according to an embodiment;

FIGS. 2A through 2E illustrate cross-sectional views of stages in a method of manufacturing the organic light-emitting display device of FIG. 1, according to an embodiment;

FIG. 3A illustrates an image showing a shape of an opening formed in a planarization layer when an exposing device is focused at a location at which the exposing device is originally focused; and

FIG. 3B illustrates an opening showing a shape of the opening formed in the planarization layer when the exposing device is focused at a location that is offset from the planarization layer by a predetermined distance.

### DETAILED DESCRIPTION

Korean Patent Application No. 10-2010-0046025, filed on May 17, 2010 in the Korean Intellectual Property Office, and entitled: “Method of Manufacturing Organic Light Emitting Display,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. In addition, it will also be understood that when a layer is referred to as being “between” two layers, it can be the only layer between the two layers, or one or more intervening layers may also be present. Like reference numerals refer to like elements throughout.

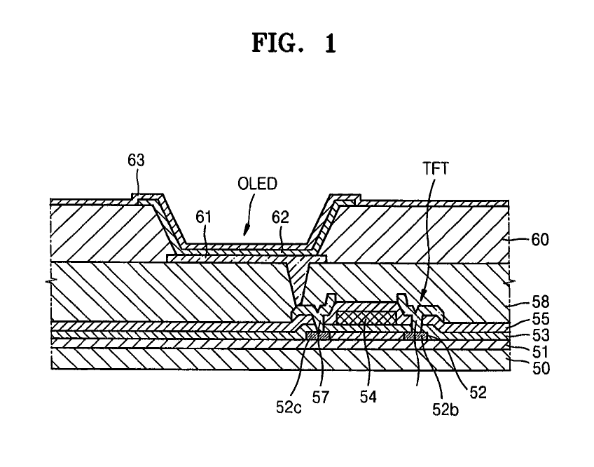

FIG. 1 illustrates a cross-sectional view of an organic light-emitting display device according to an embodiment.

Referring to FIG. 1, a thin film transistor (TFT) and an organic light-emitting diode (OLED) display device may be formed on a substrate 50. FIG. 1 shows a portion of one pixel of the organic light emitting display device. The organic light emitting display device may include a plurality of such pixels.

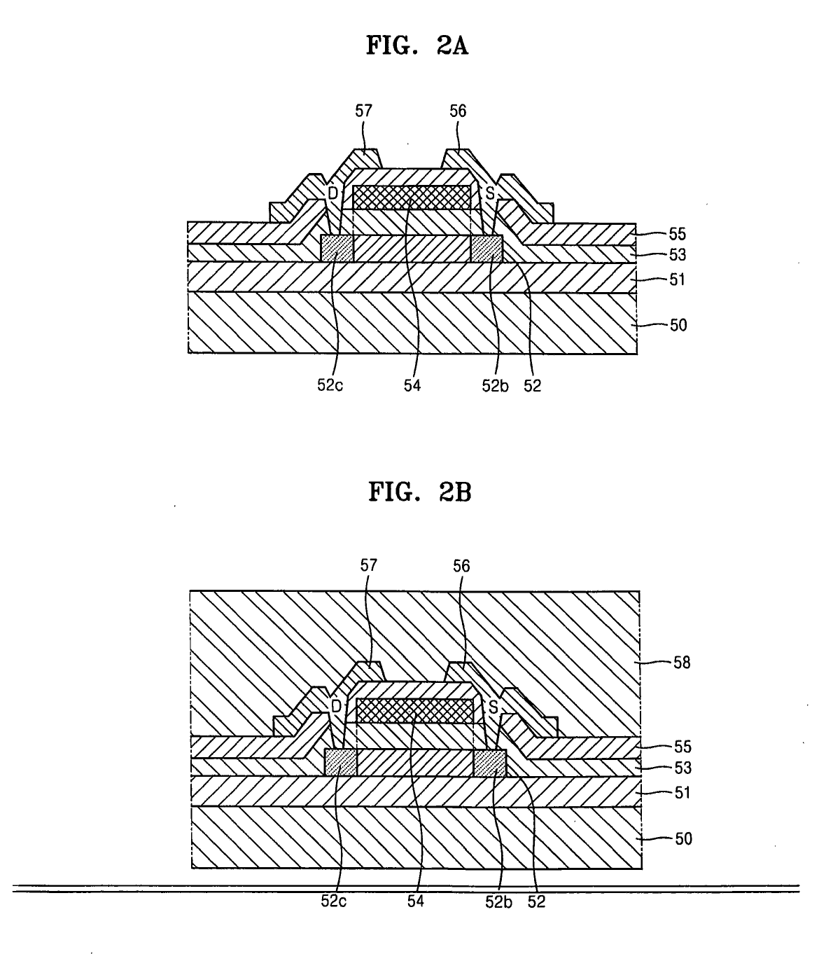

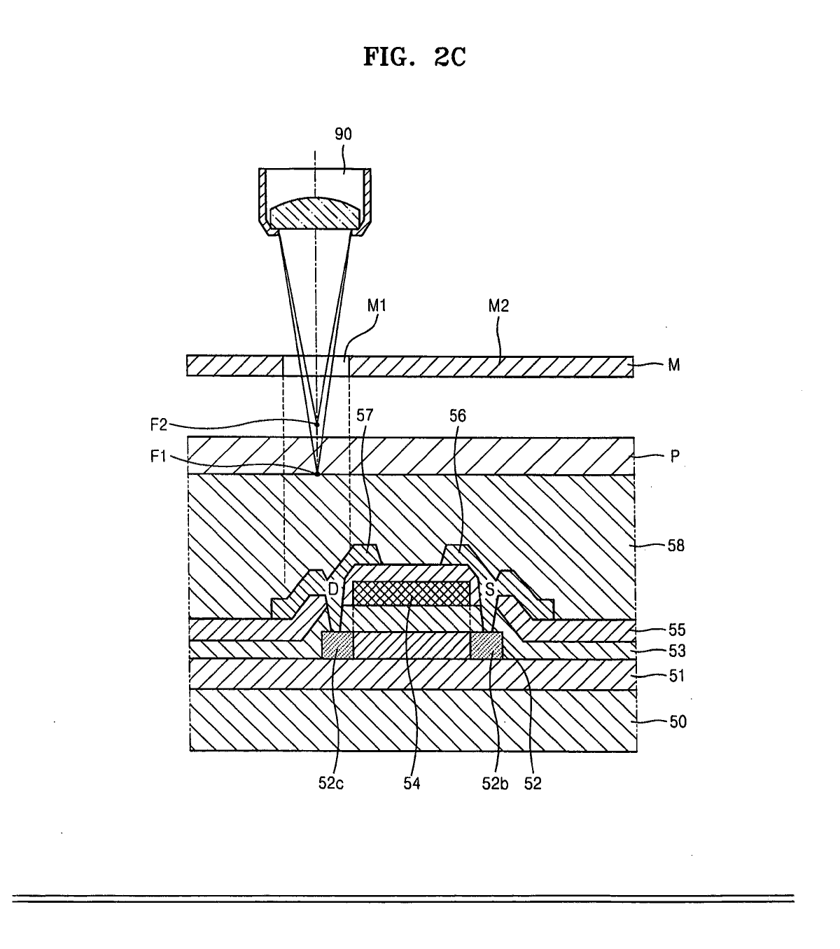

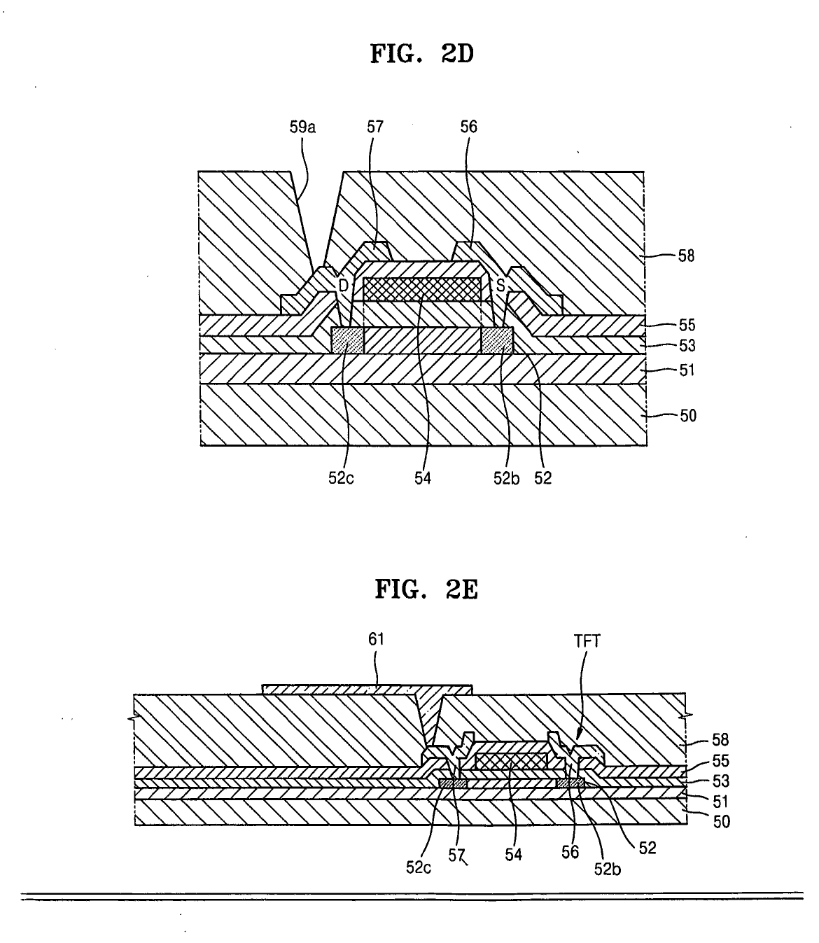

A buffer layer 51 may be formed on a, e.g., glass or plastic, substrate 50. An active layer 52 having a predetermined pattern may be formed on the buffer layer 51. A gate insulating layer 53 may be formed on the active layer 52 and the buffer layer 51. A gate electrode 54 may be formed in a predetermined region of the gate insulating layer 53. The gate electrode 54 may be connected to a gate line (not illustrated) through which a TFT ON/OFF signal may be applied. An interlayer insulating layer 55 may be formed on the gate electrode 54. Source/drain electrodes 56 and 57 may be formed to contact source/drain regions 52a and 52c, respectively, of the active layer 52 through contact holes. A planarization layer 58 may be formed of an organic material, e.g., acryl, polyimide, benzocyclobutene (BCB), or the like, on the source/drain electrodes 56 and 57. In the OLED display device according to the present embodiment, when an opening is formed in the planarization layer 58, focus of ultraviolet (UV) rays that are irradiated during an exposing process may be controlled to reduce a gradient or slope of the opening, which will be described below with reference to FIG. 2C. Although not illustrated, a passivation layer may be formed of, e.g., SiO₂, SiNₓ, or the like, on the source/drain electrodes 56 and 57, and the planarization layer 58 may be formed on the passivation layer.

A first electrode 61, which may function as an anode of an OLED, may be formed on the planarization layer 58. A pixel defining layer 60 may be formed of an organic material or an inorganic material to cover the first electrode 61. An opening may be formed in the pixel defining layer 60. Then, an organic layer 62 may be formed on a surface of the pixel defining layer 60 and on a surface of the first electrode 61 exposed through the opening. The organic layer 62 may include an emission layer. The present embodiment is not limited to the structure of the OLED described above, and various OLED structures may be applied to the present embodiment.

The OLED may display predetermined image information by emitting red, green, and/or blue light when current is applied thereto. The OLED may include the first electrode 61, which is connected to the drain electrode 56 of the TFT and to which a positive power voltage may be applied, a second electrode 63, which may be formed to cover the entire pixel and to which a negative power voltage may be applied, and the organic layer 62 between the first electrode 61 and the second electrode 63 to emit light.

The first electrode 61 and the second electrode 63 may be insulated from each other by the organic layer 62. Voltages having polarities opposite to the organic layer 62 may be respectively applied to thereby induce light emission in the organic layer 62.

The organic layer 62 may include, e.g., a low-molecular weight organic layer or a high-molecular weight organic material. When including a low-molecular weight organic layer, the organic layer 62 may have a single or multi-layer structure including at least one of a hole injection layer (HIL), a hole transport layer (HTL), an emission layer (EML), an electron transport layer (ETL), and an electron injection layer (EIL). Examples of suitable organic materials may include copper phthalocyanine (CuPc), N,N′-di(naphthalene-1-yl)-N,N′-diphenyl-benzidine (NPB), tris(8-hydroxyquinoline) aluminum (Alq3), and the like. The low-molecular weight organic layer may be formed by vacuum deposition.

When a high-molecular weight organic layer is used as the organic layer 62, the organic layer 62 may have a structure including a HTL and an EML. The HTL may be formed of, e.g., poly(ethylenedioxythiophene) (PEDOT), and the EML may be formed of, e.g., polyphenylenevinylenes (PPVs) or polyfluorenes. The HTL and the EML may be formed by, e.g., screen printing, inkjet printing, or the like.

The organic layer 62 is not limited to the organic layers described above, and may be embodied in various ways.

The first electrode 61 may function as an anode and the second electrode 63 may function as a cathode. Alternatively, the first electrode 61 may function as a cathode and the second electrode 63 may function as an anode.

The first electrode 61 may be a transparent electrode or a reflective electrode. Such a transparent electrode may be formed of, e.g., indium tin oxide (ITO), indium zinc oxide (IZO), zinc oxide (ZnO), and/or indium oxide (In₂O₃). Such a reflective electrode may be formed by forming a reflective layer of, e.g., silver (Ag), magnesium (Mg), aluminum (Al), platinum (Pt), palladium (Pd), gold (Au), nickel (Ni), neodymium (Nd), iridium (Ir), chromium (Cr), or a compound thereof, and then forming a layer of, e.g., ITO, IZO, ZnO, or In₂O₃, on the reflective layer.

The second electrode 63 may be formed as a transparent electrode or a reflective electrode. When formed as a transparent electrode, the second electrode 63 functions as a cathode. To this end, such a transparent electrode may be formed by depositing a metal having a low work function, e.g., lithium (Li), calcium (Ca), lithium fluoride/calcium (LiF/Ca), lithium fluoride/aluminum (LiF/Al), aluminum (Al), silver (Ag), magnesium (Mg), or a compound thereof, on a surface of the organic layer 62 and forming an auxiliary electrode layer or a bus electrode line thereon with a transparent electrode forming material, e.g., ITO, IZO, ZnO, In₂O₃, or the like. When the second electrode 63 is formed as a reflective electrode, the reflective layer may be formed by depositing, e.g., Li, Ca, LiF/Ca, LiF/Al, Al, Ag, Mg, or a compound thereof, on the entire surface of the organic layer 62.

A method of manufacturing an OLED display device according to an embodiment will now be described in detail.

FIGS. 2A through 2E illustrate cross-sectional views of stages in a method of manufacturing the OLED display device of FIG. 1, according to an embodiment.

Referring to FIGS. 2A through 2G, the method of manufacturing the OLED display device may include forming the TFT; forming the planarization layer 58 on the TFT; forming an opening in the planarization layer 58; and forming organic light emitting diodes that are electrically connected to the TFT through the opening.

FIG. 2A illustrates a cross-sectional view for explaining forming of the TFT on the substrate 50. The forming of the TFT has already been described above with reference to FIG. 1.

FIG. 2B illustrates a cross-sectional view for explaining forming of the planarization layer 58 on the TFT. Referring to FIG. 2B, the planarization layer 58 may be formed of an organic material, e.g., acryl, polyimide, benzocyclobutene (BCB), or the like, on the source/drain electrodes 56 and 57. The planarization layer 58 may be formed by, e.g., a chemical vapor deposition (CVD) method, a plasma enhanced (PE) CVD method, or an electron cyclotron resonance (ECR) CVD method. In FIGS. 2A and 2B, the planarization layer 58 is shown as a single layer formed of an organic material, but the embodiments are not limited thereto. That is, in an implementation, the planarization layer 58 may be formed of an organic insulating layer, as well as an organic insulating material, and may be a multi-layered structure formed by alternately forming the organic insulating layer and the inorganic layer.

FIGS. 2C and 2D illustrate cross-sectional views for explaining forming of the opening in the planarization layer 58. As shown in FIGS. 2C and 2D, exposing and developing operations may be performed on a photosensitive layer P. Then, the planarization layer 58 may be etched to form an opening 59a through which portions of the source/drain electrodes 56 and 57 are exposed.

In detail, as shown in FIG. 2C, the photosensitive film P may be formed on the planarization layer 58 and a mask M may be aligned thereon. The mask M may include a light-blocking portion M2 and a light-transmission portion M1 corresponding to a portion of the source/drain electrodes 56 and 57. The mask M including the light-transmission portion M1 and the light-blocking portion M2 may be aligned and then an exposing process may be performed on the photosensitive film P.

Then, sensitized or exposed portions of the photosensitive film P may be developed and removed. The planarization layer 58 may then be etched through removed portions of the photosensitive film P, thereby forming the opening 59a, exposing a portion of the source/drain electrodes 56 and 57 therethrough, in the planarization layer 58.

In the OLED display device according to the present embodiment, during exposing of the photosensitive layer P, a focus or focus point of UV rays irradiated during an exposing process may be controlled to reduce a gradient or slope of the resultant opening 59a formed in the planarization layer 58.

In detail, as an OLED is highly defined, it may be desirable to increase the flatness of the planarization layer 58 covering the TFT. One method of increasing the flatness of the planarization layer 58, the thickness of the planarization layer 58 formed of, e.g., acryl or the like, may be increased. However, when the thickness of the planarization layer 58 is increased in order to increase the flatness of the planarization layer 58, the gradient or slope of the opening 59a for connecting the source/drain electrodes 56 and 57 to the first electrode 61 (FIG. 1) may also be increased. In this case, during the formation of the organic layer 62 (FIG. 1) and the second electrode 63 (FIG. 1), a step difference between the organic layer 62 and the second electrode 68 may occur, and thus a short circuit between the organic layer 62 and the second electrode 68 may occur.

In the method of manufacturing the OLED display device according to the present embodiment, the focus of the UV rays that are irradiated during the exposing process of the photosensitive layer P may be offset. Thus, the thickness of the planarization layer 58 may be increased to improve the flatness of the planarization 58 while simultaneously facilitating a reduction in the gradient or slope of the resultant opening 59a in the planarization layer 58.

In particular, an exposing apparatus 90 may be focused at a location or focus point F2 that is offset by a predetermined distance from a location or focus point F1 at which the exposing apparatus 90 is focused at a surface of the planarization layer. Such an offset focus may be achieved by controlling a focus location as a parameter of the exposing apparatus 90. In particular, when the focus location is offset towards the exposing apparatus 90, i.e., further from the planarization layer 58, by the predetermined distance, since the exposing apparatus is not focused on the surface of the planarization layer 58, a boundary region between an exposed portion and non-exposed portion of the planarization layer 58 may be widened. In other words, exposed portions of the photosensitive layer P may be larger and thus portions of the planarization layer 58 exposed through the developed photosensitive layer P mask may be widened. Thus, when the planarization layer 58 is etched through the remaining portions of the exposed and developed photosensitive layer P, the gradient or slope of the opening 59a may be reduced. In an implementation, an absolute value of the distance from focus point F1 and focus point F2, e.g., the focus offset, may be about 15 μm to about 30 μm.

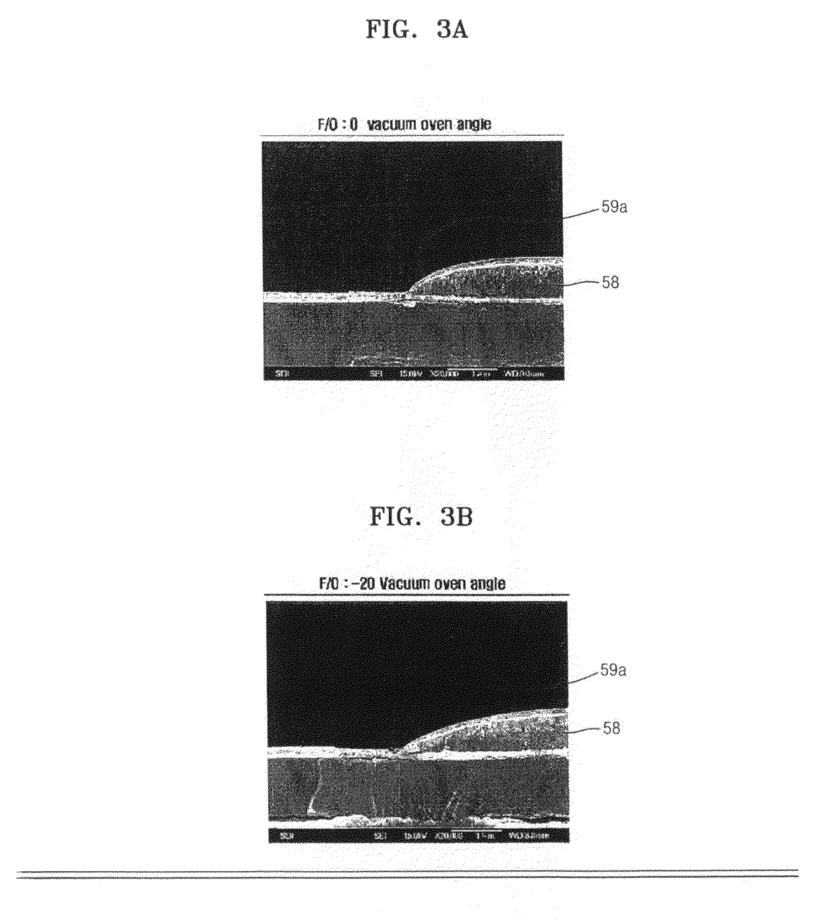

FIGS. 3A and 3B illustrate shapes of the opening 59a formed in the planarization layer 58 when the exposing apparatus 90 is focused at the location F1 at which the exposing apparatus 90 is focused, and when the exposing apparatus 90 is focused at the location F2 that is offset towards the exposing apparatus 90, respectively. In addition, the gradient of the opening 59a is illustrated.

TABLE 1

| | F/O(focus offset, μm) | N₂ Oven | Vacuum Oven |
|---|---|---|---|
| center | 0 | 56.1° | 51.6° |
| edge | 0 | 56.9° | |
| center | 20 | 45° | 38.2° |
| edge | 20 | 36.7° | |

As shown in FIGS. 3A and 3B, and Table 1, the exposing apparatus 90 is focused at the location F2 that is offset towards the exposing apparatus 90 by the predetermined distance, i.e., above the photosensitive layer P, compared with the location F1 at which the exposing apparatus 90 is focused on the surface of the planarization layer 58. Thus, the gradient or slope of the resultant opening 59a may be reduced. In detail, when the exposing apparatus 90 is focused at the location F1, that is, when an offset value of focus is 0, gradients of the opening 59a are 56.1° and 51.6°, under an N₂ atmosphere and a vacuum oven, respectively. On the other hand, when the exposing apparatus 90 is focused at the location F2 that is offset towards the exposing apparatus 90 by an offset value of 20, compared with the location F1, gradients of the opening 59a are 45.0° and 38.2°, under an N₂ atmosphere and a vacuum oven, respectively. Thus, when the focus location is changed from the location F1 to the location F2, it may be seen that the gradient or slope of the opening 59a is reduced by at least about 10°.

Then, as shown in FIG. 2E, the first electrode 61, which is electrically connected to the TFT through the opening 59a, may be formed.

Then, the pixel defining layer 60 (FIG. 1) through which a portion of the first electrode 61 is exposed may be formed. The organic layer 62 (FIG. 1) and the second electrode 63 (FIG. 1) may be formed on the first electrode 61 (FIG. 1) exposed through the pixel definition layer 60 (FIG. 1), thereby completing the manufacture of the OLED display device FIG. 1.

According to one or more embodiments, short circuits of an electrode may be prevented by increasing the thickness of a planarization layer and simultaneously increasing the flatness of the planarization layer.

In addition, the flatness of the planarization layer may be increased while simultaneously facilitating a reduction in the gradient or slope of a resultant opening formed in the planarization layer, thereby reducing an error rate.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A method of manufacturing an organic light-emitting display device, the method comprising:
forming a thin film transistor (TFT);
forming a planarization layer on the TFT;
forming an opening in the planarization layer; and
forming an organic light emitting diode that is electrically connected to the TFT through the opening,
wherein forming the opening in the planarization layer includes:
forming a photosensitive layer on the planarization layer, and
irradiating light on the photosensitive layer such that the light has a focus point offset from a surface of the planarization layer to control a gradient of the opening.

2. The method as claimed in claim 1, wherein the focus point of light irradiated onto the photosensitive layer is offset away from the TFT to reduce the gradient of the opening.

3. The method as claimed in claim 1, wherein the planarization layer includes at least one of acryl, polyimide, and benzocyclobutene (BCB).

4. The method as claimed in claim 1, wherein forming the opening in the planarization layer includes:
aligning a mask on the photosensitive film,
removing portions of the photosensitive layer irradiated with the light, and
etching the planarization layer through removed portions of the photosensitive layer.

5. The method as claimed in claim 4, wherein irradiating light on the photosensitive layer includes offsetting the focus of light that is irradiated thereon.

6. The method as claimed in claim 5, wherein offsetting the focus of light includes offsetting the focus point by about 15 μm to about 30 μm.

7. The method as claimed in claim 1, wherein forming the organic light emitting diode that is electrically connected to the TFT through the opening includes:
forming a plurality of first electrodes that are electrically connected to the TFT through the opening;
forming a plurality of pixel defining layers between the first electrodes;
forming a plurality of organic layers on the first electrodes; and
forming a second electrode on the pixel defining layers and the organic layers.

8. The method as claimed in claim 1, wherein irradiating the light on the photosensitive layer such that the light has a focus point offset from a surface of the planarization layer includes offsetting the focus point by about 15 μm to about 30 μm from the surface of planarization layer.
